(19) United States
(12) Patent Application Publication
(10) Pub. No.: US 2012/0168135 A1
(43) Pub. Date: Jul. 5, 2012

(54) APPARATUS AND METHOD FOR SOLAR CELL MODULE EDGE COOLING DURING LAMINATION

(75) Inventors: Robert C. LINKE, Mountain View, CA (US); Martin S. WOHLERT, San Jose, CA (US); Adam BRAND, Palo Alto, CA (US); Ofer AMIR, Half Monn Bay, CA (US)

(73) Assignee: APPLIED MATERIALS, INC., Santa Clara, CA (US)

(21) Appl. No.: 13/327,369

(22) Filed: Dec. 15, 2011

Related U.S. Application Data
(60) Provisional application No. 61/429,840, filed on Jan. 5, 2011.

(51) Int. Cl. F28F 7/00; H01L 31/18

(52) U.S. Cl. 165/138; 29/714; 29/738

(57) ABSTRACT

Embodiments of the present invention provide a lamination module and procedure for cooling the edges of a partially formed thin film solar module to substantially the same temperature as the central region of the module just prior to compressing and bonding the layers of the heated module. The lamination module may include a cooling module having a plurality of nozzles configured to apply a curtain of cooling fluid to leading and trailing edges of the partially formed solar module after heating the module and just prior to compressing the module. The nozzles may further be configured to apply a curtain of cooling fluid to side edges of the partially formed solar cell module as it passes through the cooling module. As a result, the chance of bubble formation within the bonding material in the edge regions of the completed solar cell module is significantly lowered with respect to conventional lamination processes.

### CROSS-REFERENCE TO RELATED APPLICATIONS

This application claims benefit of U.S. provisional patent application Ser. No. 61/429,840, filed Jan. 5, 2011, which is herein incorporated by reference.

### BACKGROUND OF THE INVENTION

1. Field of the Invention

Embodiments of the present invention generally relate to a lamination module and process for cooling the edge regions of a partially formed thin film solar module prior to compression and bonding of the solar module.

2. Description of the Related Art

Solar cells are devices that convert sunlight into electrical power. Thin film solar cells have a substrate with a plurality of layers formed thereon. The plurality of film layers typically includes a front electrode film disposed on the substrate, one or more active regions formed on the front electrode, and a back electrode formed on the one or more active regions. The film layers are generally scribed to form a plurality of solar cells connected in series to form a solar module. The solar module further includes a layer of bonding material sandwiched or laminated between the film layers formed on the substrate and a back substrate.

During a conventional thin film solar module formation process, a partially formed solar module (i.e., substrate with thin films, bonding material, and back substrate) is heated in a heating module to an acceptable bonding temperature, and the partially formed solar module is then placed under compression forces to laminate or bond the layers together. Importantly, the lamination process needs to be performed to minimize or eliminate the formation of bubbles in the bonding material.

It has been found that conventional lamination processes lead to bubble formation within the bonding material found in the edge regions of partially formed thin film solar modules. Bubbles formed in the bonding material of a fully formed thin film solar module are aesthetically displeasing, which is unacceptable in certain applications, such as building integrated photovoltaic modules. Furthermore, bubbles formed in the bonding material in edge or corner regions of thin film solar modules are pathways for contamination and/or corrosive attack of the film layers or other internal components of the fully formed solar module that may lead to reduced thin film solar module performance or thin film solar module failure.

Therefore, a need exists for improved thin film solar module lamination modules and processes that reduce or eliminate the formation of bubbles within the edge and corner regions of the modules.

### SUMMARY OF THE INVENTION

In one embodiment of the invention, an apparatus for solar cell module edge cooling during lamination comprises one or more rollers positioned to support a heated solar cell module, one or more glass sensors positioned to detect an edge region of the solar cell module while the solar cell module is disposed on the one or more rollers, and a fluid delivery system positioned to apply a fluid to the edge region of the solar cell module while the solar cell module is disposed on the one or more rollers.

In another embodiment, a method of solar cell module edge cooling during lamination comprises detecting a leading edge of a solar cell module, advancing the leading edge of the solar cell module relative to a plurality of nozzles, and delivering a cooling fluid to the leading edge of the solar cell module through the plurality of nozzles.

In yet another embodiment, an apparatus for hermetically sealing a solar cell module comprises a heating module, a cooling module positioned to receive a solar cell module from the heating module, and a compression module positioned to receive the solar cell module from the cooling module. The heating module has at least one heating element and is configured to heat the solar cell module. The cooling module comprises a fluid delivery system having a fluid source and a plurality of nozzles in fluid communication with the fluid source. The plurality of nozzles is positioned to apply a fluid to an edge region of the solar cell module. The compression module comprises at least a pair of compression rollers configured to apply opposing forces on an upper and lower side of the solar cell module sufficient to compress at least one layer of the solar cell module.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic, plan view of an example of a thin film solar cell module.

FIG. 1B is a schematic, cross-sectional view of a portion of the thin film solar cell module of FIG. 1A taken along section line A-A.

FIG. 1C is a schematic, plan view of a partially formed solar cell module having a central region and edge region.

FIG. 2A is a schematic, cross-sectional view of a lamination module according to one embodiment of the present invention.

FIG. 2B is a schematic, top view of the heating module from FIG. 2A having select upper components removed for clarity.

FIG. 2C is a schematic, cross-sectional view of the heating module from FIG. 2B taken about the section line C-C.

FIG. 3 is a schematic diagram of a fluid delivery system according to one embodiment.

FIGS. 4A-4D are schematic, side views of portions of an edge cooling module depicting the operation thereof according to one embodiment.

### DETAILED DESCRIPTION

It has been found that conventional heating of a thin film solar module during the lamination process results in significantly higher temperatures in the edge regions of the module than in the remaining central region. It has also been found that completing the lamination process (i.e., compression and bonding steps) with excess temperatures in the edge regions of the module with respect to the central region of the module results in significant bubble formation in the bonding material situated in the edge regions, which provides a path for contamination and corrosive attack to certain layers of the solar module. Embodiments of the present invention provide a lamination module and procedure for cooling the edges of the module to substantially the same temperature as the central region of the module just prior to compressing and bonding the layers of the heated module. As a result, the chance of bubble formation within the bonding material is significantly lowered with respect to conventional lamination processes.

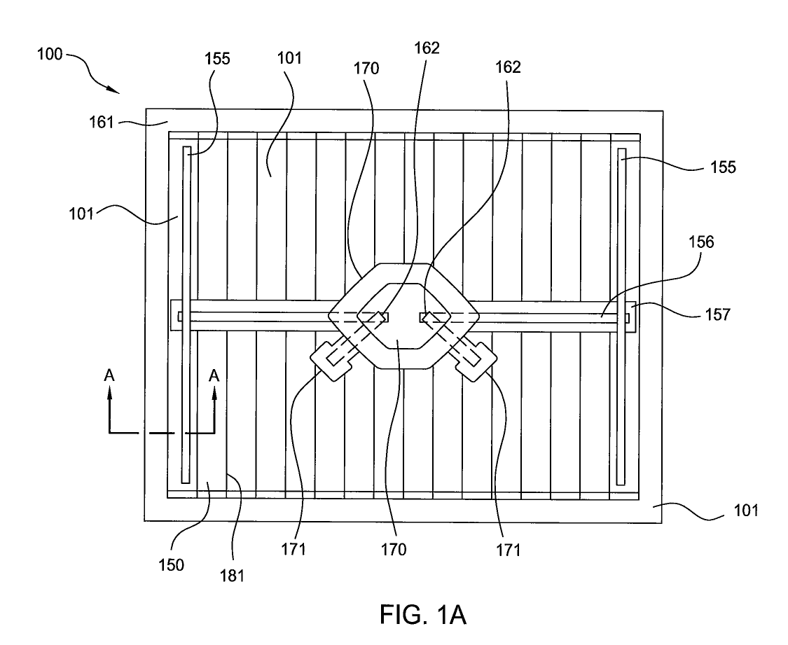

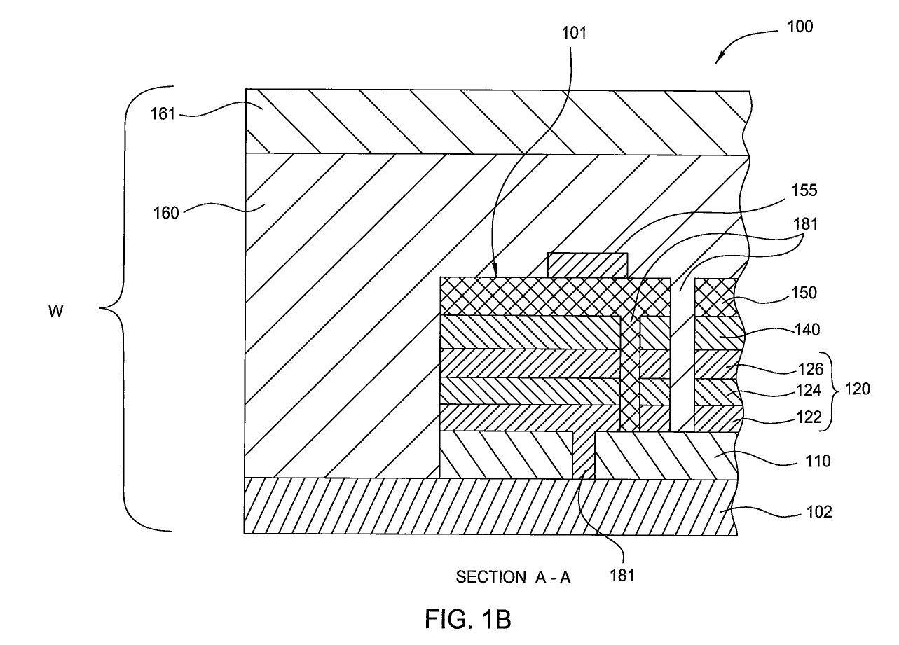

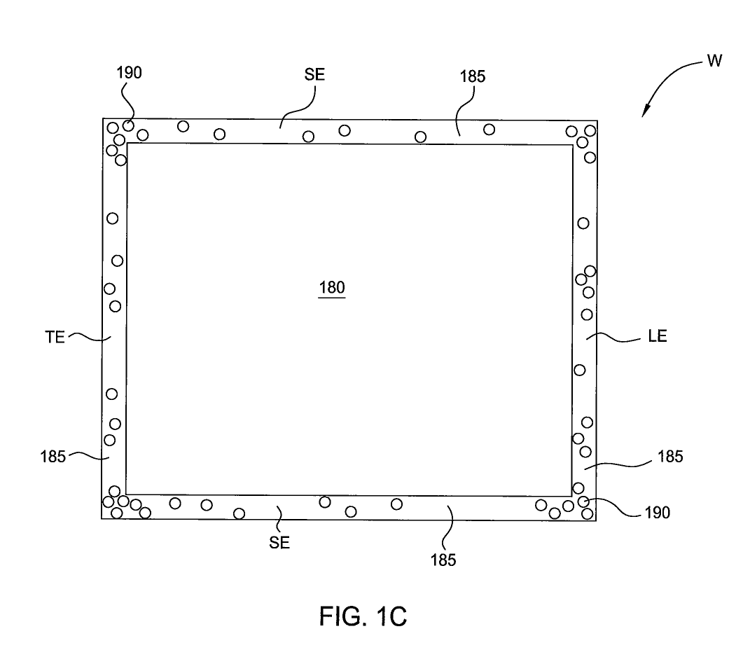

FIG. 1A is a schematic, plan view of an example of a thin film solar cell module 100. FIG. 1B is a schematic, cross-sectional view of a portion of the thin film solar cell module 100 along section line A-A. As shown in FIGS. 1A and 1B, the solar cell module 100 includes a substrate 102, such as a glass, polymer or metal substrate. The substrate 102 has a first transparent conducting oxide (TCO) layer 110 (e.g., zinc oxide (ZnO), tin oxide (SnO)) formed thereon. A p-i-n junction 120 is formed on the first TCO layer 110. In the example shown in FIG. 1B, a single p-i-n junction is shown; however, in other examples, p-i-n junction 120 may include multiple p-i-n junctions.

The p-i-n junction 120 includes a p-type amorphous silicon layer 122, an intrinsic type amorphous silicon layer 124 formed on the p-type amorphous silicon layer 122, and an n-type microcrystalline silicon layer 126 formed on the intrinsic type amorphous silicon layer 124. In one example, the p-type amorphous silicon layer 122 is formed to a thickness between about 60 Å and about 300 Å, the intrinsic type amorphous silicon layer 124 is formed to a thickness between about 1500 Å and about 3500 Å, and the n-type microcrystalline silicon layer 126 is formed to a thickness between about 100 Å and about 400 Å.

A second TCO layer 140 may be formed on the p-i-n junction 120, and a back contact layer 150 may be formed on the second TCO layer 140. The back contact layer 150 may include one or more of aluminum, silver, titanium, chromium, nickel, vanadium, gold, copper, and platinum.

Trenches 181 are formed in the layers (110, 122, 124, 126, 140, and 150), as shown, to divide the solar cell module 100 into a plurality of serially connected solar cells 101. An insulating strip 157, such as insulating tape, is applied across the back contact layer 150, and a cross buss 156 is applied on the insulating strip 157 as shown in FIG. 1A. Then, a side buss 155 is formed across the back contact layer 150 of the outermost solar cells 101 as shown. In one example, both the side buss 155 and cross buss 156 are metal strips, such as copper tape, nickel coated silver ribbon, silver coated nickel ribbon, tin coated copper ribbon, nickel coated copper ribbon, or the like. The side buss 155 is in direct electrical contact with the cross buss 156.

A bonding material 160 is applied to the module 100 and a back glass substrate 161 is positioned on the opposite side of the bonding material 160. The solar module 100 is then laminated to seal and protect the thin films and other internal components of the solar module 100. The bonding material 160 may be a sheet of polymeric material, such as polyvinyl Butyral (PVB) or ethylene vinyl acetate (EVA).

As shown in FIG. 1A, a hole is typically formed in the back glass substrate 161 prior to positioning it on the bonding material. The area of the hole within the solar module 100 remains at least partially uncovered by the bonding material 160 to allow the ends of the cross buss 156 to remain exposed through the hole. The end of each cross buss 156 has one or more leads 162 used to connect the cross buss 156 (and in turn, the side buss 155) to electrical connections 171 found in a junction box 170, which is sealed to the back glass substrate 161 and used to connect the solar module 100 to external electrical components.

To prevent confusion, a partially formed solar module 100 having the bonding material 160 and the back glass substrate 161 disposed thereon prior to attaching the junction box 170 is referred to hereinafter as a substrate W.

FIG. 1C is a schematic plan view of a substrate W depicting a central region 180 and edge region 185 as used throughout the present application. The edge region 185 is a thin strip (e.g., 25-50 mm) around the perimeter of the substrate W. It should be noted that the edge region 185 described herein is a thermal region and should be distinguished from an edge deletion region of a solar module, which is an area where deposited material is removed from the solar module. The central region 180 is the remainder of the substrate W extending inwardly from the edge region 185. As previously described, bubbles may develop within the bonding material 160 in certain circumstances. In particular, it has been found that bubbles 190 tend to develop in the edge region 185 of the substrate W due at least in part to excessive heating in the edge region 185 during the lamination process. For instance, it has been found that heating a substrate W until the central region 180 of the substrate W reaches a uniform temperature of about 80° C. in a conventional heating module results in the edge region 185 reaching a temperature of between about 90° C. and about 105° C. In other examples, it has been found that heating a substrate W until the central region 180 of the substrate W reaches a uniform temperature of about 90° C. in a conventional heating module results in portions of the edge region 185 (e.g., corner regions) reaching a temperature of between about 120 ° C. and about 140° C. It has been further found that completing the lamination process with such a temperature difference between the edge region 185 and central region 180 of the substrate W results in excessive bubble formation in the bonding material 160 within the edge region 185 of the substrate W. In order to prevent such overheating, and subsequent bubble formation, in the edge region 185 of the substrate W during lamination, a lamination module and laminating process in accordance with the present invention has been developed.

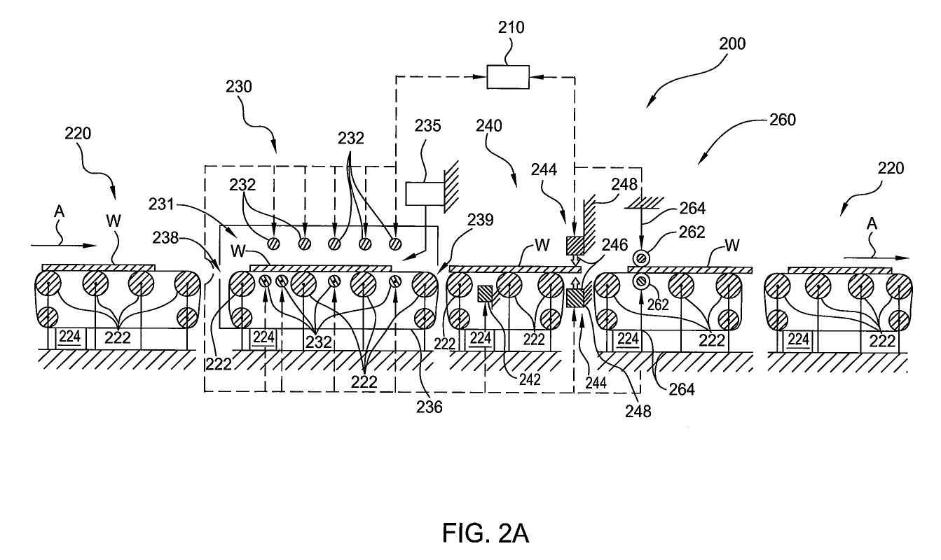

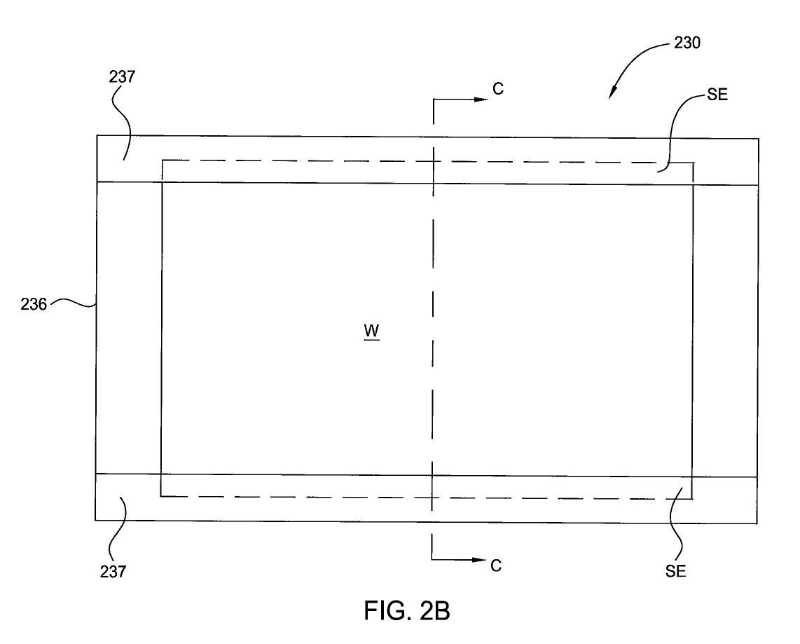

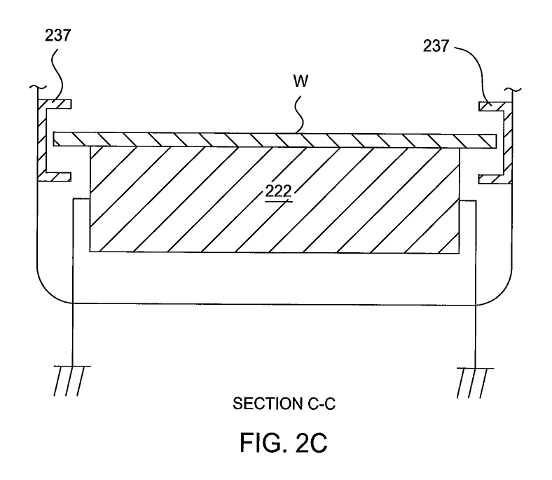

FIG. 2A is a schematic, cross-sectional view of a lamination module 200 according to one embodiment of the present invention. The lamination module 200 generally includes a system controller 210, one or more conveying modules 220, a heating module 230, an edge cooling module 240, and a compression module 260. As shown in the FIG. 2A, a substrate W may be transferred into and through the lamination module 200 following a path A. The conveying module(s) 220 generally include rollers 222 and actuators 224, such as one or more motors and belts, that are collectively configured to support, move, and position a substrate W controlled by commands from the system controller 210.

The system controller 210 is adapted to control the various components of the lamination module 200. The system controller 210 generally includes a central processing unit (CPU) (not shown), memory (not shown), and support circuits (not shown). The CPU may be one of any form of computer processor used in industrial settings for controlling system hardware and processes. The memory is connected to the CPU and may be one or more of a readily available memory, such as random access memory (RAM), read only memory (ROM), floppy disk, hard disk, or any other form of digital storage, local or remote. Software instructions and data can be coded and stored within the memory for instruction the CPU. The support circuits are also connected to the CPU for supporting the processor in a conventional manner. The support circuits may include cache, power supplies, clock circuits, input/output circuitry subsystems, and the like. A program (instructions) readable by the system controller 210 determines which tasks are performable on a substrate W. For example, the program includes instructions readable by the system controller 210 that includes code to perform tasks relating to monitoring, executing, and controlling the movement, support, and positioning of a substrate W along with various process recipe tasks to be performed in the lamination module 200.

One of the conveyor modules 220 may be positioned to receive a substrate W from an upstream processing module, such as a pre-heat and compression module, and transfer the substrate W into the heating module 230 along the path A. The heating module 230 includes a plurality of rollers 222 and actuators 224, such as one or more motors and belts, that are collectively configured to support, move, and position the substrate W within a processing region 231 of the heating module 230 as controlled by commands from the system controller 210. The heating module 230 further includes a plurality of heating elements 232 and an enclosure 236 to enclose the processing region 231 of the heating module. The enclosure generally has an inlet port 238 through which the substrate W is received and an outlet port 239 through which the substrate W is transferred out of the heating module 230.

The heating elements 232 are typically arranged on each side of the substrate W as shown in FIG. 2A. The heating elements 232 may be heating lamps (e.g., infrared lamps), resistive heating elements, or other heat generating devices that are controlled by the system controller 210 to deliver a desired amount of heat to the substrate W during processing. The heating elements 232 may be elongated members oriented substantially perpendicular to the direction of travel of the substrate W as it is moved through the processing region 231. In one example, the heating elements 232 are configured and controlled to heat the processing region 231 to a temperature between about 240° C. and about 280° C., resulting in a substrate W temperature of between about 70° C. and about 105° C.

In a preferred example, the heating module 230 is controlled to heat the central region 180 of the substrate W to a temperature between about 75° C. and about 85° C.

The heating module 230 may also include a fluid delivery system 235 that is used to deliver a desired flow of fluid through the processing region 231 during processing to provide more uniform convective heat transfer to the substrate W. In one example, the fluid delivery system 235 is a fan assembly that is configured to deliver a desired flow of air across the substrate W disposed in the processing region 231 controlled by commands sent from the system controller 210.

FIG. 2B is a schematic, top view of the heating module 230 with the upper portion of the enclosure 236 and upper heating elements 232 removed for clarity. FIG. 2C is a schematic, cross-sectional view of the heating module 230 taken about the section line C-C. In one configuration, the heating module 230 includes heat blocking members 237, such as bars or channels, positioned on each side of the heating module 230. The heat blocking members 237 may be made of a metallic material, such as aluminum, formed into a C-shape as shown in FIG. 2C. The heat blocking members 237 are positioned to overlap both the upper and lower side edge regions (SE) of the substrate W as it is transferred through the heating module 230 in order to block a portion of the heat transfer to the corresponding side edge regions (SE) of the substrate W. Lowering the temperature of the side edge regions (SE) of the substrate W (e.g., 25-50 mm strip along each edge) has been found to reduce the formation of bubbles within the bonding material 160 of the solar cell module 100 during lamination.

In one example, the heating module 230 is configured to heat the substrate W to an overall temperature of about 80° C. throughout the central region 180 of the substrate W. Such heating in a conventional manner generally results in the edge region 185 (i.e., 25-50 mm strip along each edge) of the substrate W to reach temperatures between about 90° C. and about 95° C. In such an example, lowering the temperature in the edge region 185 back down to about 80° C. (i.e., substantially uniform with the remainder of the substrate W) has been found to dramatically reduce the formation of bubbles within the bonding material 160 in the edge region 185 of the substrate W during subsequent compression/bonding steps. In general, it has been found that reducing the temperature in the edge region 185 between about 10° C. and about 15° C. dramatically reduces the formation of bubbles within the bonding material 160 in the edge region 185 of the substrate W during subsequent compression/bonding steps.

The edge cooling module 240 includes a plurality of rollers 222 and actuators 224, such as one or more motors and belts, that are collectively configured to receive the substrate W from the heating module 230 and support, move, and position the substrate W within the cooling module 240 controlled by commands sent by the system controller 210. The edge cooling module 240 further includes one or more glass sensors 242 in communication with the system controller 210 and a fluid delivery system 244 controlled by the system controller 210. The glass sensors 242 are configured and positioned to detect the leading and/or trailing edges of the substrate W as it is moved through the edge cooling module 240 and send corresponding signals to the system controller 210. The fluid delivery system 244 is configured to apply a cooling fluid to select edge regions of the substrate W as it is moved through the edge cooling module 240.

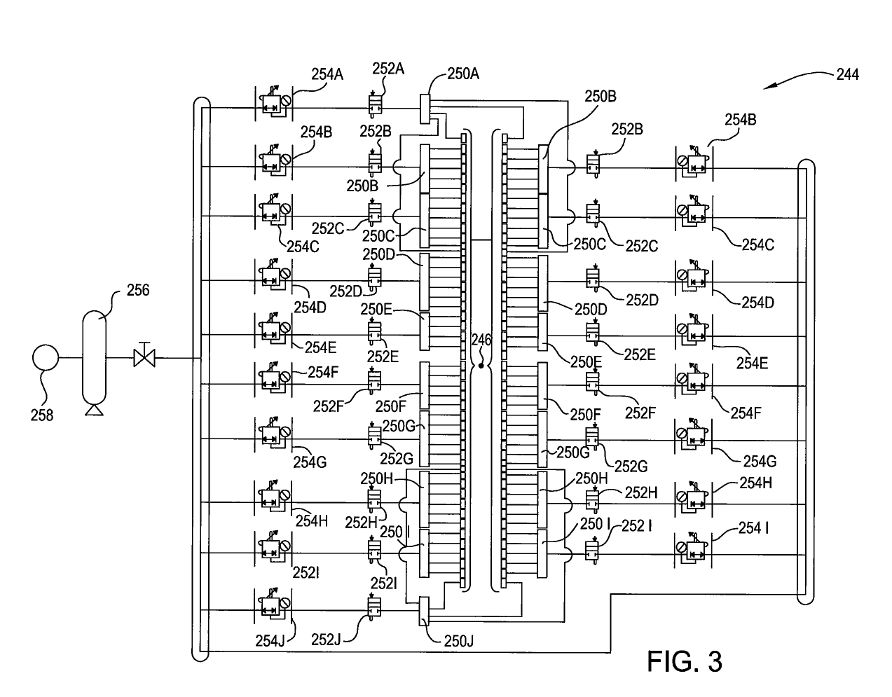

FIG. 3 is a schematic diagram of the fluid delivery system 244. Referring to FIGS. 2A and 3, the fluid delivery system 244 includes a plurality of nozzles 246 mounted to support rails 248 above and below the substrate W as it is moved through the edge cooling module 240. In one example, the nozzles 246 are positioned and configured to distribute a flat fan of compressed air transversely across the substrate W. An example of such a nozzle is a WINDJET® model AA727 nozzle manufactured by Spraying Systems Co. in Wheaton, Illinois. The nozzles 246 may be grouped into banks 250A-250J. Each bank 250A-250J is in fluid communication with a solenoid valve 252A-252J and pressure regulator 254A-254J, which is each controlled by commands from the system controller 210. Each pressure regulator 254A-254J may be in fluid communication with an air tank 256 supplied by an air compressor 258. In another example, pneumatic valves and orifices are used rather than solenoid valves and pressure regulators.

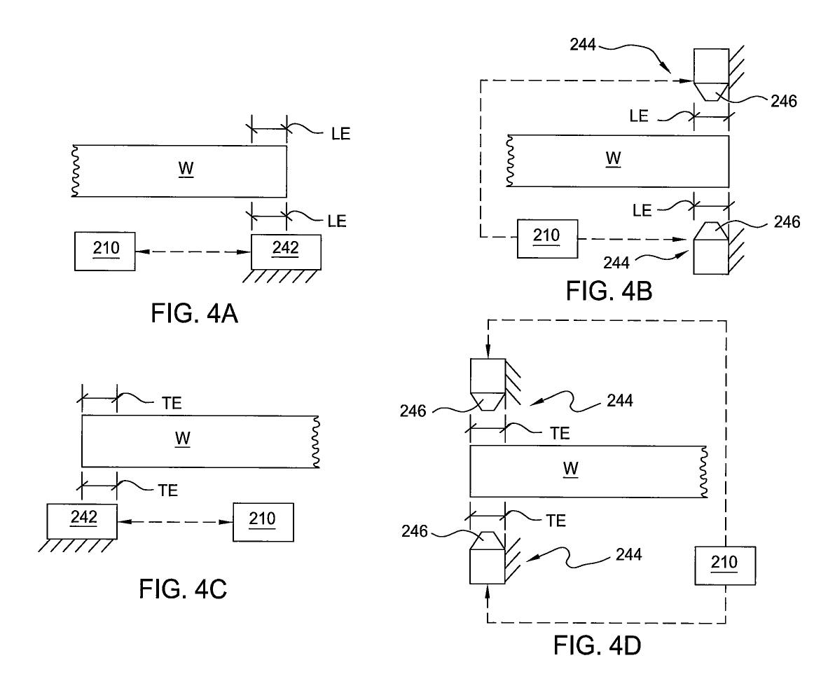

FIGS. 4A-4D are schematic, side views of portions of the edge cooling module 240 depicting the operation thereof. Referring to FIGS. 1C, 3, and 4A-4B, in operation, the glass sensor(s) 242 detect a leading edge (LE) of the substrate W as it is received by the edge cooling module 240 as shown in FIG. 4A. The glass sensor(s) 242 send signals to the system controller 210 indicating that the leading edge (LE) of the substrate W has been received. The system controller 210 sends signals to control the movement and positioning of the substrate W and the distribution of compressed air from the fluid delivery system 244. As the leading edge (LE) of the substrate W (e.g., 25-50 mm strip) is positioned adjacent the nozzles 246, the system controller 210 activates all of the solenoid valves 252A-252J to supply compressed air to all of the banks of nozzles 246 to spray a curtain of clean dry air on the leading edge (LE) of the substrate W, such that the leading edge (LE) of the substrate W is cooled to a temperature between about 75° C. and about 85° C. In one example, the substrate W is received with a central region 180 temperature of about 80° C. and a leading edge (LE) temperature of between about 90° C. and about 105° C. In this example, a curtain of clean dry air is supplied to the leading edge (LE) at a flow rate of between about 500 L/sec and about 600 L/sec for about two seconds in order to cool the leading edge (LE) to a temperature substantially equivalent to the central region 180 of the substrate W (i.e., about 80° C.). It should be noted that all flow rates described herein are relative to standard conditions of 1 atm and 15.6° C. In one example, only a half-long or a quarter-sized substrate W is processed in the edge cooling module 240. In such a situation, the substrate is centered in the cooling module 240, and only solenoid valves 252A, 252D-G, and 252J are activated rather than all of the solenoid valves. In addition, when processing a half-long or quarter-sized substrate W, certain nozzles within banks 250A and 250J are not needed and are plugged, while the pressure regulators 254A and 254J are adjusted for lower flow.

Referring to FIGS. 1C, 3, and 4C-4D, the substrate W is continually advanced until a trailing edge (TE) is detected by the glass sensor(s) 242. The glass sensor(s) 242 send signals to the system controller 210 indicating that the trailing edge (TE) of the substrate W has been received. The system controller 210 sends signals to control the movement and positioning of the substrate W and the distribution of compressed air from the fluid delivery system 244. As the trailing edge (TE) of the substrate W (e.g., 25-50 mm strip) is positioned adjacent the nozzles 246, the system controller 210 activates all of the solenoid valves 252A-252J to supply compressed air to all of the banks of nozzles 246 to spray a curtain of clean dry air on the trailing edge (TE) of the substrate W, such that the trailing edge (TE) of the substrate W is cooled to a temperature between about 75° C. and about 85° C. In one example, the substrate W is received with central region 180 temperature of about 80° C. and a trailing edge (TE) temperature of between about 90° C. and about 105° C. In this example, a curtain of clean dry air is supplied to the trailing edge (TE) at a flow rate of between about 500 L/sec and about 600 L/sec for about two seconds in order to cool the trailing edge (TE) to a temperature substantially equivalent to the central region 180 of the substrate W (i.e., about 80° C.). In one example, only a half-long or a quarter-sized substrate W is processed in the edge cooling module 240. In such a situation, only solenoid valves 252A, 252D-G, and 252J are activated rather than all of the solenoid valves. In addition, when processing a half-long or quarter-sized substrate W, certain nozzles within banks 250A and 250J are not needed and are plugged, while the pressure regulators 254A and 254J are adjusted for lower flow. In one example, the trailing edge (TE) of the substrate W is not detected by the glass sensor(s), rather the system controller 210 uses a timing mechanism to determine when the trailing edge (TE) is positioned adjacent the nozzles 246.

In one example, after the leading edge (LE) of the substrate W has moved beyond the nozzles 246, the system controller 210 sends signals to all of the solenoid valves 252A-252J to stop the flow of compressed air to all of the banks 250A-250J of nozzles 246 until the trailing edge (TE) is positioned adjacent the nozzles 246. In another example, the system controller 210 sends signals to solenoid valves 252B-2521 to stop the flow of compressed air to banks 250B-2501 of nozzles 246, but the flow of compressed air is continued through banks 250A and 250J of nozzles 246 to cool side edges (SE) (e.g., 25-50 mm strip) of the substrate W to a temperature between about 75° C. and about 85° C. In one example, the substrate W is received with a central region 180 temperature of about 80° C. and side edge (SE) temperatures of between about 90° C. and about 105° C. In this example, a curtain of clean dry air is supplied to the side edges (SE) at a flow rate of between about 15 L/sec and about 30 L/sec for between about 20 seconds and about 50 or more seconds, depending on the length of the substrate W, in order to cool the side edges (SE) to a temperature substantially equivalent to the remainder of the substrate W (i.e., about 80° C.). In one example, flow to certain nozzles 246 within the banks 250A and 250J are controlled so that no air is supplied to the central region 180 of the substrate W. In an example wherein only a half-long or a quarter-sized substrate W is processed by the cooling module 240, air is only continued through banks 250A and 250J of nozzles 246 to cool the side edges (SE) of the substrate W. In addition, when processing a half-long or quarter-sized substrate W, certain nozzles within banks 250A and 250J are not needed and are plugged, while the pressure regulators 254A and 254J are adjusted for lower flow.

Referring back to FIG. 2A, after the substrate W has been heated and the edges cooled, it is transferred to the compression module 260. The compression module 260 includes a plurality of rollers 222 and actuators 224, such as one or more motors and belts, that are collectively configured to receive the substrate W from the cooling module 240 and support, move, and position the substrate W controlled by the system controller 210. The compression module 260 further includes a plurality of compression rollers 262 and actuators 264, such as pneumatic or hydraulic cylinders, configured to apply compression forces to the heated substrate W to bond the layers together. In one example, a pair of compression rollers 262 is used to apply a compression force of between about 200 N/cm and about 600 N/cm to uniformly compress the heated substrate W in order to bond the layers of the substrate W together and eliminate bubbles within the bonding material 160 (see FIG. 1B). The substrate W is then transferred out of the compression module 260 using the rollers 222 to a conveyor module 220 to be transported to downstream modules for completing the solar module fabrication process.

As previously set forth, it has been found that conventional heating of a partially formed solar module during the lamination process results in significantly higher temperatures in the edge regions of the module than in the remaining central region. It has also been found that completing the lamination process (i.e., compression and bonding steps) with excess temperatures in the edge regions with respect to the central region of the module results in significant bubble formation in the bonding material situated in the edge regions, which provides a path for contamination and corrosive attack to certain layers of the solar module. Embodiments of the present invention, as described above, provide a lamination module and procedure for cooling the edges of the module to substantially the same temperature as the central region of the module just prior to compressing and bonding the layers of the heated module. As a result, the chance of bubble formation within the bonding material is significantly lowered with respect to conventional lamination processes.

While the foregoing is directed to embodiments of the present invention, other and further embodiments of the invention may be devised without departing from the basic scope thereof, and the scope thereof is determined by the claims that follow. For instance, the present invention has been described with reference to full, half-long, and quarter-sized substrates; however, the invention is equally applicable and may be adapted to accommodate half-short substrates and a variety of other sized substrates as well. Additionally, although primarily described with respect to thin film solar modules, the processes described herein may also be applicable to other to other laminated materials (e.g., windows, plywood).

1. An apparatus for solar cell module edge cooling during lamination, comprising:
one or more rollers positioned to support a heated solar cell module;
one or more glass sensors positioned to detect an edge region of the solar cell module while the solar cell module is disposed on the one or more rollers; and
a fluid delivery system positioned to apply a fluid to the edge region of the solar cell module while the solar cell module is disposed on the one or more rollers.

2. The apparatus of claim 1, wherein the fluid delivery system comprises:
a fluid source;
a plurality of nozzles in fluid communication with the fluid source; and
a plurality of valves positioned between the fluid source and the plurality of nozzles.

3. The apparatus of claim 2, wherein the plurality of nozzles comprises:
a first row of nozzles positioned above the solar cell module as it is disposed on the one or more rollers; and
a second row of nozzles positioned below the solar cell module as it is disposed on the one or more rollers.

4. The apparatus of claim 3, wherein the one or more glass sensors are configured to send signals to a controller when the edge region is detected.

5. The apparatus of claim 4, wherein the controller is configured to receive the signals from the one or more glass sensors and send corresponding signals to the plurality of valves to control flow of the fluid from the fluid source to the nozzles when the edge region of the solar cell module is positioned adjacent the plurality of nozzles.

6. The apparatus of claim 5, wherein the edge region comprises the leading edge of the solar cell module as it is advanced through the apparatus, wherein the leading edge includes a strip on the upper and lower surfaces of the solar cell module.

7. The apparatus of claim 6, wherein the edge region further comprises the trailing edge of the solar cell module as it is advanced through the apparatus, wherein the trailing edge includes a strip on the upper and lower surfaces of the solar cell module.

8. The apparatus of claim 7, wherein the controller is further configured to control the plurality of valves to apply cooling fluid to side edges of the solar cell module between the leading and trailing edges as the solar cell module is advanced through the apparatus, wherein the side edges include strips on the upper and lower surfaces of the solar cell module.

9. The apparatus of claim 1, further comprising a plurality of heat blocking members positioned to overlap the edge region of the solar cell module while the solar cell module is disposed on the one or more rollers.

10. A method of solar cell module edge cooling during lamination, comprising:
detecting a leading edge of a solar cell module;
advancing the leading edge of the solar cell module relative to a plurality of nozzles; and
delivering a cooling fluid to the leading edge of the solar cell module through the plurality of nozzles.

11. The method of claim 10, wherein delivering the cooling fluid comprises delivering cooling fluid to a first leading edge region on an upper surface of the solar cell module and a second leading edge region on a lower surface of the solar cell module.

12. The method of claim 11, further comprising:
detecting a trailing edge of the solar cell module; and
delivering cooling fluid to the trailing edge through the plurality of nozzles.

13. The method of claim 10, wherein delivering the cooling fluid to the trailing edge comprises delivering cooling fluid to a first trailing edge region on the upper surface of the solar cell module and a second trailing edge region on the lower surface of the solar cell module.

14. The method of claim 10, wherein delivering the cooling fluid to the trailing edge comprises tracking elapsed time from detecting the leading edge and delivering the cooling fluid based on the tracked time.

15. The method of claim 10, further comprising applying cooling fluid to a side edge of the solar cell module through a portion of the plurality of nozzles, wherein applying the cooling fluid to the side edge comprises applying cooling fluid to a first side region on the upper surface of the solar cell module and a second side region on the lower surface of the solar cell module.

16. An apparatus for hermetically sealing a solar cell module, comprising:
a heating module having at least one heating element and configured to heat a solar cell module;
a cooling module positioned to receive the solar cell module from the heating module and comprising a fluid delivery system having a fluid source and a plurality of nozzles in fluid communication with the fluid source, wherein the plurality of nozzles is positioned to apply a fluid to an edge region of the solar cell module; and
a compression module comprising at least a pair of compression rollers and positioned to receive the solar cell module from the cooling module and apply opposing forces on an upper and lower side of the solar cell module sufficient to compress at least one layer of the solar cell module.

17. The apparatus of claim 16, wherein the cooling module further comprises a plurality of heat blocking members positioned to overlap the edge region of the solar cell module.

18. The apparatus of claim 16, wherein the cooling module further comprises:
one or more rollers configured to support the solar cell module; and
one or more glass sensors positioned to detect the edge region of the solar cell module and send corresponding signals to a controller, wherein the controller is configured to receive the signals from the one or more glass sensors and send signals to the fluid delivery system to control flow of the fluid from the fluid source to the nozzles when the edge region is positioned adjacent the plurality of nozzles.

19. The apparatus of claim 18, wherein the plurality of nozzles comprises:
a first row of nozzles positioned above the solar cell module as it is disposed on the one or more rollers; and
a second row of nozzles positioned below the solar cell module as it is disposed on the one or more rollers.

20. The apparatus of claim 19, wherein the edge region comprises the leading edge of the solar cell module as it is advanced through the cooling module, wherein the leading edge includes a strip on the upper and lower surfaces of the solar cell module.
